(19) United States
(12) Patent Application Publication
(10) Pub. No.: US 2021/0002759 A1
(43) Pub. Date: Jan. 7, 2021

(54) DIAMOND-LIKE CARBON SYNTHESIZED BY ATMOSPHERIC PLASMA

(71) Applicant: SAMU TECHNOLOGY, LLC, Fremont, CA (US)

(72) Inventors: Jinqiu Zhang, Pleasanton, CA (US); Xiaobo Huang, Fremont, CA (US); Masahiro Osugi, Fremont, CA (US)

(21) Appl. No.: 16/918,609

(22) Filed: Jul. 1, 2020

Related U.S. Application Data
(60) Provisional application No. 62/921,656, filed on Jul. 1, 2019.

(51) Int. Cl. C23C 16/27; H01J 37/32

(52) U.S. Cl. CPC C23C 16/274; H01J 37/32183; C23C 16/272; H01J 37/32201; H01J 37/32596; H01J 37/3244

(57) ABSTRACT

A system includes a structure including an upper chamber linked to a lower chamber, the upper chamber including a gas inlet configured to enable a gas to enter the upper chamber, the lower chamber including a plasma outlet, a microwave generator configured to deliver a microwave to the upper chamber causing atoms in the gas to ionize to generate a charged particle microwave plasma, a hollow cathode centrally positioned within the lower chamber and an anode surrounding an interior wall of the lower chamber, and a power source for generating power, the power flowing between the anode and the hollow cathode causing atoms in the gas to ionize to generate a charged particle hollow cathode plasma.

### CROSS-REFERENCE TO RELATED APPLICATIONS

This application claims benefit from U.S. Provisional Patent Application Ser. No. 62/921,656, filed Jul. 1, 2019, which is incorporated by reference in its entirety.

### BACKGROUND OF THE INVENTION

The present invention is generally related to coatings, and more particularly to diamond-like carbon synthesized by atmospheric plasma.

In general, Diamond-like carbon (DLC) is a class of amorphous carbon material that displays some of the typical properties of diamond. DLC is a mixture of Sp³ bonded diamond structure and Sp² bonded graphite structure, DLC is usually applied as coatings to other materials that could benefit from some of those properties.

Current DLC coating technologies depend on vacuum technology, which make DLC coatings on large surfaces and inner surfaces of a specific surface difficult.

### BRIEF SUMMARY OF THE INVENTION

The following presents a simplified summary of the innovation in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

In general, in one aspect, the invention features a system including a tube having a gas inlet and a plasma outlet, the tube configured to generate a plasma, a helical coil surrounding a surface of the tube, a radio frequency generator, and a matching box, the helical coil linked to matching box, the radio frequency generator linked to the matching box.

In another aspect, the invention features a method including a shell having a gas inlet and a plasma outlet, a refractory tube included in the shell, the refractory tube including an orifice to the plasma outlet, a hollow cathode centrally positioned within the refractory tube, an anode surrounding an interior wall of the refractory tube, an anode surrounding an interior wall of the refractory tube, wherein application of power between the anode and the hollow cathode causes atoms in the gas to ionize to generate a charged particle plasma.

In still another aspect, the invention features a system including a structure including an upper chamber linked to a lower chamber, the upper chamber including a gas inlet configured to enable a gas to enter the upper chamber, the lower chamber including a plasma outlet, a microwave generator configured to deliver a microwave to the upper chamber causing atoms in the gas to ionize to generate a charged particle microwave plasma, a hollow cathode centrally positioned within the lower chamber and an anode surrounding an interior wall of the lower chamber, and a power source for generating power, the current flowing between the anode and the hollow cathode causing atoms in the gas to ionize to generate a charged particle hollow cathode plasma.

In yet another aspect, the invention features a method of synthesizing diamond-like carbon by atmospheric plasma including introducing a gas into an inlet of a first chamber of a quartz tube, applying electromagnetic radiation in a microwave range to the gas, causing atoms in the gas to ionize to generate a charged particle microwave plasma, receiving the gas in a second chamber of the quartz tube, the second chamber including a hollow cathode centrally positioned within and an anode surrounding an interior wall, applying power to the second chamber to enable a current to flow between the hollow cathode and anode, causing atoms in the gas to ionize to generate a charged particle hollow cathode plasma, and releasing the microwave plasma and hollow cathode plasma through a plasma outlet as a plume plasma.

The invention may include one or more of the following advantages.

Systems of the present invention generate a DLC without the need of a the vacuum system

Systems of the present invention generate a high density plasma.

Systems of the present invention generate a plasma that can be irradiated directly to an object.

Systems of the present invention are applicable to things that cannot be placed in a vacuum.

Systems of the present invention generate a low temperature plasma that can be used to irradiate substances sensitive to heat.

These and other features and advantages will be apparent from a reading of the following detailed description and a review of the associated drawings. It is to be understood that both the foregoing general description and the following detailed description are explanatory only and are not restrictive of aspects as claimed.

### BRIEF DESCRIPTION OF THE DRAWINGS

These and other features, aspects, and advantages of the present invention will become better understood with reference to the following description, appended claims, and accompanying drawings where:

FIG. 1 is a block diagram of a first embodiment of an exemplary diamond-like carbon synthesis system.

FIG. 2 is a flow diagram.

FIG. 3 is a block diagram of a second embodiment of an exemplary diamond-like carbon synthesis system.

FIG. 4 is flow diagram.

FIG. 5 is a block diagram of a third embodiment of an exemplary diamond-like carbon synthesis system.

FIG. 6 is a flow diagram.

### DETAILED DESCRIPTION OF THE INVENTION

The subject innovation is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

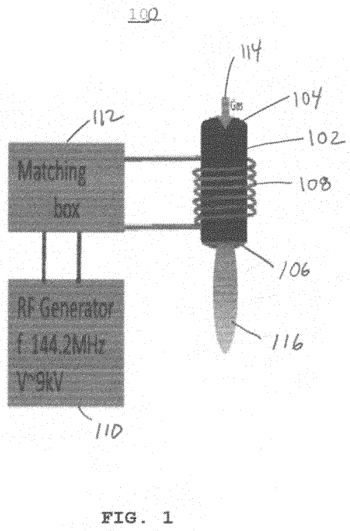

As shown in FIG. 1, a first embodiment of an exemplary diamond-like carbon synthesis system 100, also referred as a inductive discharge type I system, includes a tube 102 having a gas inlet 104 and a plasma outlet 106. The tube 102 may be constructed of, for example, quartz or ceramic, or other materials. An exterior surface of the tube 102 is surrounded by helical coil 108. The helical coil 108 is linked to radio frequency (RF) generator 110 through a matching box 112.

In operation, a gas 114 is introduced into a chamber of the tube 102 and a diamond-like carbon (DLC) plasma 116 is generated within the tube 102. DLC is a class of amorphous carbon material that displays some of the typical properties of diamond. DLC is usually applied as coatings to other materials that could benefit from some of those properties. The gas 114 includes a mixture of at least two gases, i.e., a carbon containing gas and an inert gas. The carbon containing gas may include, for example, acetylene (C₂H₂), methane (CH₄), or other carbon containing gas. The inert gas may include, for example, argon (Ar), helium (He), or other inert gas.

When the gas 114 is within the chamber of the tube 102, RF power is transmitted from the RF generator 110 to the chamber through the matching box 112. The application of power causes the atoms in the gas 114 to either gain or lose electrons (ionization) and the end result is a charged particle plasma. The matching box 112 is used to match an impedance between a transmitter and a receiver by tuning a series adjustable capacitor and a parallel capacitor. More specifically, the RF power generator 110, the matching box 112, the helical coil 108 and plasma constitute a circuit loop, and by adjusting the matching box 112 the plasma output 116 can be made more stable. In this manner, the DLC output 116 is made by atmospheric plasma that does not depend on any type of vacuum technology.

The DLC coating 116 is generated using high wattage and low current. For example, an average applied voltage range is 9 kilovolts (kv). An average applied current range in less than 1 amp (A) and preferably between 400-500 mA. An average applied power range is preferably less than 50 watts (W) and typically does not exceed 100 W. An average power is preferably less than 50 watts (W) and typically not greater than 100 W. The temperature range of the plasma being generated is preferably less than 100° C.

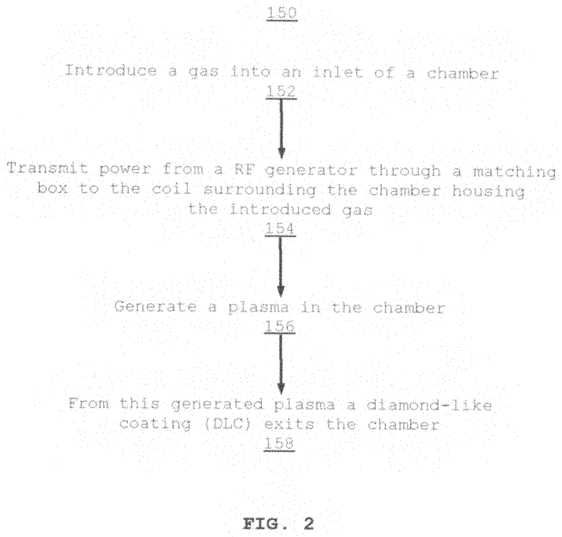

As shown in FIG. 2, a process 150 for synthesizing diamond-like carbon (DLC) by atmospheric plasma includes introducing (152) a gas into an inlet of a chamber.

The chamber may constructed of, for example, quartz or ceramic, or other materials. An exterior surface of the tube is surrounded by helical coil. The helical coil linked to a radio frequency (RF) generator through a matching box.

The introduced gas may include a mixture of at least two gases, i.e., a carbon containing gas and an inert gas. The carbon containing gas may include, for example, acetylene (C₂H₂), methane (CH₄), or other carbon containing gas.

Process 150 transmits (154) power from a RF generator through a matching box to the coil surrounding the chamber housing the introduced gas.

Process 150 generates (156) a plasma in the chamber and from this generated plasma a diamond-like coating (DLC) exits (158) the chamber.

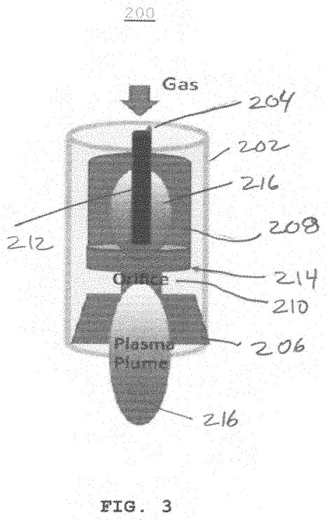

As shown in FIG. 3, a second embodiment of an exemplary diamond-like carbon synthesis system 200, also referred as a type II hollow cathode plasma with orifice system, is illustrated in cross-section and includes a shell 202 having a gas inlet 204 and a plasma outlet 206. The shell 202 includes a refractory tube 208, also referred to as a cathode plasma generation chamber. The refractory tube 208 includes an orifice 210 that is an opening from the refractory tube 208 to the plasma outlet 206.

A hollow cathode 212 is centrally positioned within the refractory tube 208 while an anode 214 surrounds an interior wall of the refractory tube 208. Application of power between the anode 214 and the hollow cathode 212 causes a generation of a plasma 216, i.e., the current flowing between the anode 214 and the hollow cathode 212 causes the atoms in the gas to either gain or lose electrons (ionization) and the end result is a charged particle plasma.

More specifically, gas entering the gas inlet 204 enters the refractory tube 208 and application of power across the anode 214 generates a plasma. The gas entering the gas inlet 204 includes a mixture of at least two gases, i.e., a carbon containing gas and an inert gas. The carbon containing gas may include, for example, acetylene (C₂H₂), methane (CH₄), or other carbon containing gas.

Generated plasma is compressed in the orifice 210, making a plume plasma 216 (i.e., DLC coating) exiting the more dense.

Here again, a temperature range of the plume plasma 216 being generated is typically less than 100° C.

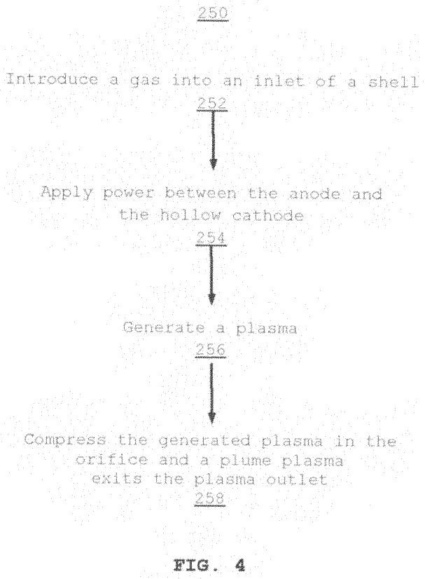

As shown in FIG. 4, a process 250 for synthesizing diamond-like carbon (DLC) by atmospheric plasma includes introducing (252) a gas into an inlet of a shell. The introduced gas may include a mixture of at least two gases, i.e., a carbon containing gas and an inert gas. The carbon containing gas may include, for example, acetylene (C₂H₂), methane (CH₄), or other carbon containing gas.

The shell includes a refractory tube, also referred to as a cathode plasma generation chamber. The refractory tube includes an orifice that is an opening from the refractory tube to a plasma outlet on the shell.

A hollow cathode is centrally positioned within the refractory tube while an anode 214 surrounds an interior wall of the refractory tube.

Process 250 applies (254) power between the anode and the hollow cathode which generates (256) a plasma.

Process 250 compresses (258) the generated plasma in the orifice and a plume plasma exits the plasma outlet.

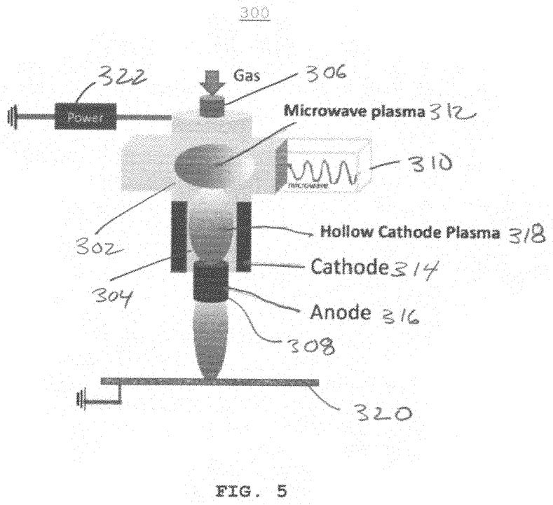

As shown in FIG. 5, a third embodiment of an exemplary diamond-like carbon synthesis system 300, also referred as a type III microwave plasma/hollow cathode discharge type combination system, includes an upper chamber 302 linked to a lower chamber 304. The upper chamber 302 includes a gas inlet 306 while the lower chamber 304 includes a plasma outlet 308. A microwave generator 310 is linked to the upper chamber 302. In one implementation, at 2.4 GHz frequency, the microwave generator 310 delivers microwave to the upper chamber 302, causing gas entering through the gas inlet 306 and into the upper chamber to generate a microwave plasma 312.

The lower chamber 304 includes a hollow cathode 314 centrally positioned within and an anode 316 surrounding an interior wall. Application of power between the anode 316 and the hollow cathode 314 causes a generation of a hollow cathode plasma 318. A power source 322 generates pulse DC power across the cathode 314 and anode 316 of the lower chamber 304 to generate the hollow cathode plasma 318. Subsequently, a DLC coating exits the plasma outlet 308, which may be deposited on a surface 320.

Gas flowing into the gas inlet 306 includes a mixture of at least two gases, i.e., a carbon containing gas and an inert gas. The carbon containing gas may include, for example, acetylene (C₂H₂), methane (CH₄), or other carbon containing gas.

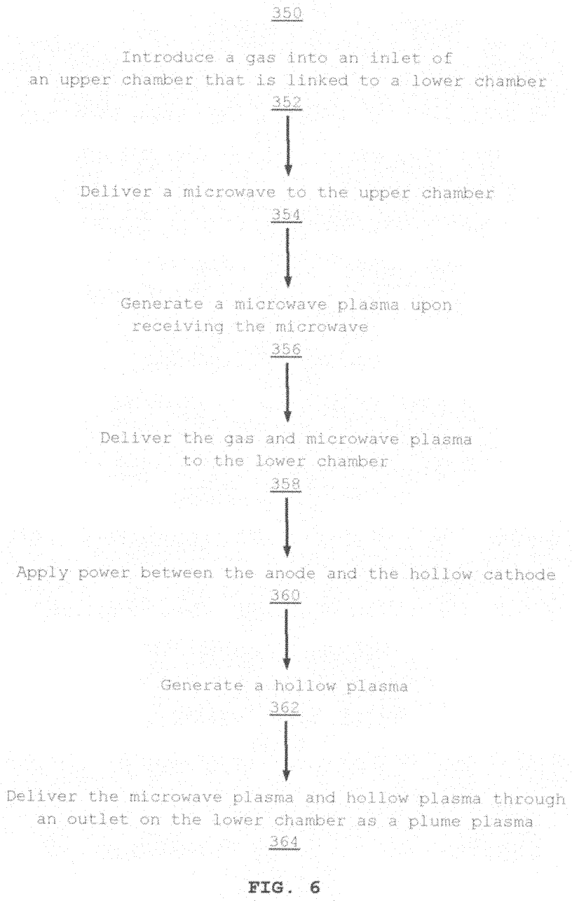

As shown in FIG. 6, a process 350 for synthesizing diamond-like carbon (DLC) by atmospheric plasma includes introducing (352) a gas into an inlet of an upper chamber that is linked to a lower chamber. The introduced gas may include a mixture of at least two gases, i.e., a carbon containing gas and an inert gas. The carbon containing gas may include, for example, acetylene (C₂H₂), methane (CH₄), or other carbon containing gas. The upper chamber is linked to a microwave generator.

Process 350 delivers (354) a microwave to the upper chamber.

Process 350 generates (356) a microwave plasma upon receiving the microwave.

Process 350 delivers (358) the gas and microwave plasma to the lower chamber. The lower chamber includes a hollow cathode centrally positioned within and an anode surrounding an interior wall.

Process 350 applies (360) power between the anode and the hollow cathode and generates (362) a hollow cathode plasma.

Process 350 delivers (364) the microwave plasma and hollow cathode plasma through an outlet on the lower chamber as a plume plasma.

It would be appreciated by those skilled in the art that various changes and modifications can be made to the illustrated embodiments without departing from the spirit of the present invention. All such modifications and changes are intended to be within the scope of the present invention except as limited by the scope of the appended claims.

What is claimed:

1. A system comprising:
a tube having a gas inlet and a plasma outlet, the tube configured to generate a plasma;
a helical coil surrounding a surface of the tube;
a radio frequency generator; and
a matching box, the helical coil linked to the matching box, the radio frequency generator linked to the matching box.

2. The system of claim 1 wherein the tube is constructed from quartz or ceramic.

3. The system of claim 1 wherein the gas inlet is configured to enable a gas to enter a chamber of the tube.

4. The system of claim 3 wherein the gas is a mixture of a carbon containing gas and an inert gas.

5. The system of claim 4 wherein the carbon containing gas is selected from the group consisting of acetylene (C₂H₂) and methane (CH₄).

6. The system of claim 5 wherein the inert gas is selected from the group consisting of argon (Ar) and helium (He).

7. The system of claim 4 wherein the radio frequency generator has a high wattage and a low current.

8. A system comprising:
a shell having a gas inlet and a plasma outlet;
a refractory tube included in the shell, the refractory tube including an orifice to the plasma outlet;
a hollow cathode centrally positioned within the refractory tube;
an anode surrounding an interior wall of the refractory tube, wherein application of power between the anode and the hollow cathode causes atoms in the gas to ionize to generate a charged particle plasma.

9. The system of claim 8 further comprising a gas passing through the gas inlet and into the refractory tube, the gas including a mixture of a carbon containing gas and an inert gas.

10. The system of claim 9 wherein the orifice is configured to compress the generated plasma, making it more dense.

11. The system of claim 10 wherein the carbon containing gas is selected from the group consisting of acetylene (C₂H₂) and methane (CH₄).

12. The system of claim 11 wherein the inert gas is selected from the group consisting of argon (Ar) and helium (He).

13. A system comprising:
a structure comprising an upper chamber linked to a lower chamber, the upper chamber including a gas inlet configured to enable a gas to enter the upper chamber, the lower chamber including a plasma outlet;
a microwave generator configured to deliver a microwave to the upper chamber causing atoms in the gas to ionize to generate a charged particle microwave plasma;
a hollow cathode centrally positioned within the lower chamber and an anode surrounding an interior wall of the lower chamber; and
a power source for generating power, the power flowing between the anode and the hollow cathode causing atoms in the gas to ionize to generate a charged particle hollow cathode plasma.

14. The system of claim 13 wherein the gas comprises a mixture of a carbon containing gas and an inert gas.

15. The system of claim 14 wherein the carbon containing gas is selected from the group consisting of acetylene (C₂H₂) and methane (CH₄).

16. The system of claim 15 wherein the inert gas is selected from the group consisting of argon (Ar) and helium (He).

17. A method of synthesizing diamond-like carbon by atmospheric plasma comprising:
introducing a gas into an inlet of a first chamber of a quartz tube;
applying electromagnetic radiation in a microwave range to the gas, causing atoms in the gas to ionize to generate a charged particle microwave plasma;
receiving the gas in a second chamber of the quartz tube, the second chamber comprising a hollow cathode centrally positioned within and an anode surrounding an interior wall;
applying power to the second chamber to enable a current to flow between the hollow cathode and anode, causing atoms in the gas to ionize to generate a charged particle hollow cathode plasma; and
releasing the microwave plasma and hollow cathode plasma through a plasma outlet as a plume plasma.

18. The method of claim 17 wherein the microwave range is a frequency between 300 MHz (1 m) and 300 GHz (1 mm).

19. The method of claim 18 wherein the gas comprises a carbon containing gas and an inert gas.

20. The method of claim 19 wherein the carbon containing gas is selected from the group consisting of acetylene (C₂H₂) and methane (CH₄); and
wherein the inert gas is selected from the group consisting of argon (Ar) and helium (He).
